(19) United States
(12) Patent Application Publication
(10) Pub. No.: US 2011/0058348 A1
(43) Pub. Date: Mar. 10, 2011

(54) SEMICONDUCTOR DEVICE

(75) Inventors: Atsushi SAKAI, Ogaki-shi (JP); Shinobu Kato, Ogaki-shi (JP); Naoyuki Jinbo, Ogaki-shi (JP)

(73) Assignee: IBIDEN CO., LTD., Ogaki-shi (JP)

(21) Appl. No.: 12/795,258

(22) Filed: Jun. 7, 2010

Related U.S. Application Data
(60) Provisional application No. 61/241,123, filed on Sep. 10, 2009.

(51) Int. Cl. H05K 1/11

(52) U.S. Cl. 361/803

(57) ABSTRACT

A semiconductor device includes a first substrate having a power-source line, an IC device mounted on the first substrate and having a power-source line, a second substrate mounted on the IC device and having a base material, a power-source layer formed inside or on a surface of the base material, an insulation layer formed on the power-source layer, and a pad formed on the insulation layer, and a via conductor connecting the power-source layer and the pad. A first route connects the power-source line of the first substrate and the power-source line of the IC device. A second route connects the power-source line of the first substrate and the power-source layer of the second substrate. A third route connects the power-source layer of the second substrate and the power-source line of the IC device.

### CROSS-REFERENCE TO RELATED APPLICATIONS

The present application claims the benefits of priority to U.S. Application No. 61/241,123, filed Sep. 10, 2009. The contents of that application are incorporated herein by reference in their entirety.

### BACKGROUND OF THE INVENTION

1. Field of the Invention

The present invention relates to an SiP (System-in-Package) semiconductor device having a chip-stack structure formed by laminating semiconductor chips three-dimensionally.

2. Discussion of the Background

When laminating semiconductor chips three-dimensionally on a package substrate, other than a method in which each semiconductor chip is connected to the package substrate by wire bonding, there is a method as described in Japanese Laid-Open Patent Publication 2005-72596 in which through-silicon vias penetrating an upper surface and a lower surface are formed in each semiconductor chip so as to reduce wiring length, and the semiconductor chips positioned above or below each other are connected by means of the through-silicon vias. The contents of this publication are incorporated herein by reference in their entirety.

### SUMMARY OF THE INVENTION

According to one aspect of the present invention, a semiconductor device includes a first substrate having a power-source line, an IC device mounted on the first substrate and having a power-source line, a second substrate mounted on the IC device and having a base material, a power-source layer formed inside or on a surface of the base material, an insulation layer formed on the power-source layer, and a pad formed on the insulation layer, and a via conductor connecting the power-source layer and the pad. A first route connects the power-source line of the first substrate and the power-source line of the IC device. A second route connects the power-source line of the first substrate and the power-source layer of the second substrate. A third route connects the power-source layer of the second substrate and the power-source line of the IC device.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 are cross-sectional views of a semiconductor device according to the first embodiment of the present invention;

FIG. 2 is a view showing the bottom surface of a second substrate of the first embodiment;

FIG. 3 are views showing the steps of a method for manufacturing a second substrate according to the first embodiment;

FIG. 4 are views showing the steps of a method for manufacturing a semiconductor device according to the first embodiment;

FIG. 5 are views showing the steps of a method for manufacturing a semiconductor device according to the first embodiment;

FIG. 6 are views showing the steps of a method for manufacturing a semiconductor device according to the first modified example of the first embodiment;

FIG. 7 are views showing the steps of a method for manufacturing a semiconductor device according to the first modified example of the first embodiment;

FIG. 8 are views showing the steps of a method for manufacturing a semiconductor device according to the second modified example of the first embodiment;

FIG. 9 are cross-sectional views of a semiconductor device according to the second embodiment; and

FIG. 10 are views showing the steps of a method for manufacturing a semiconductor device according to the second embodiment.

### DETAILED DESCRIPTION OF THE EMBODIMENTS

The embodiments will now be described with reference to the accompanying drawings, wherein like reference numerals designate corresponding or identical elements throughout the various drawings.

### First Embodiment

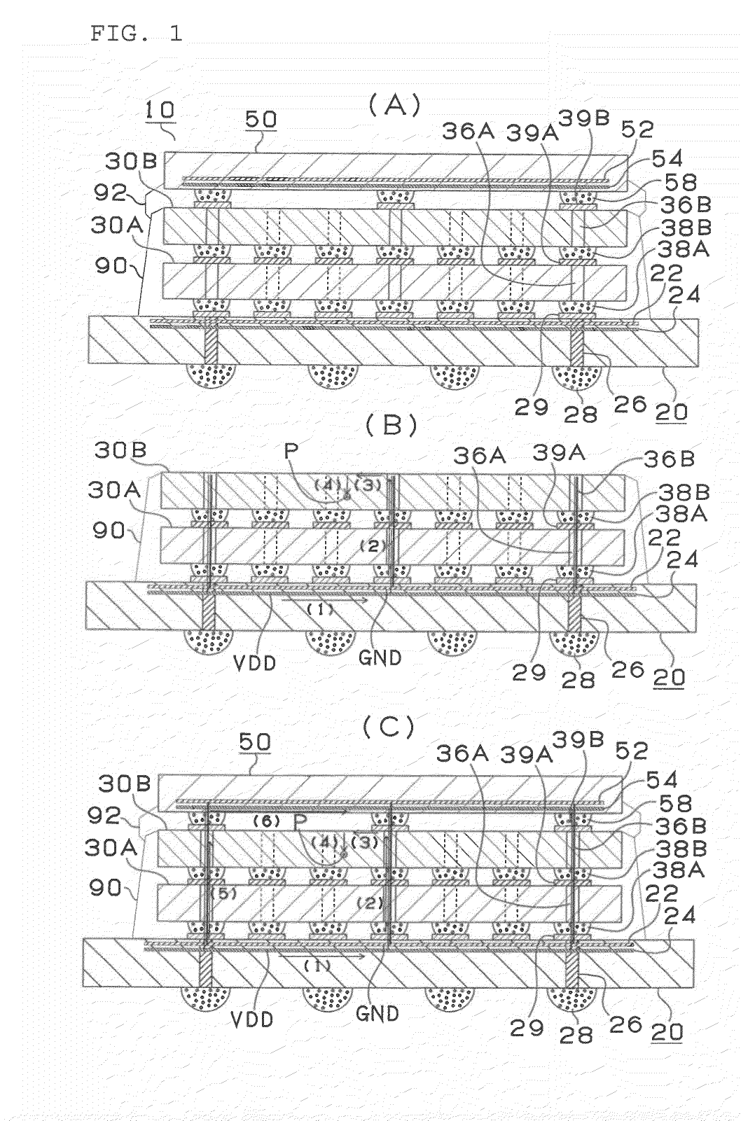

A semiconductor device according to the first embodiment of the present invention is described with reference to a schematic view shown in FIG. 1A. Semiconductor device 10 is formed with first substrate 20 to be mounted on an external substrate, first IC chip (30A) to be mounted on first substrate 20, second IC chip (30B) to be mounted on first IC chip (30A), and second substrate 50 to be mounted on second IC chip (30B).

First substrate (such as a printed wiring board or a silicon interposer) 20 has solder bumps 28 to be mounted on an external printed wiring board (such as a motherboard), through holes 26 connecting the upper-surface side and the lower-surface side, power-source layer 24, ground layer 22 and pads 29. Solder bumps 28, through holes 26 and pads 29 are the following: those for signal transmission which are not connected to the power-source layer or the ground layer, those for power source which are connected to the power-source layer, and those for ground which are connected to the ground layer.

First IC chip (30A) has through-silicon vias (36A) connecting the upper-surface side and the lower-surface side, solder bumps (38A) on the lower-surface side, and pads (39A) on the upper-surface side. Through-silicon vias (36A), solder bumps (38A) and pads (39A) are the following: those for signal transmission which are not connected to the power-source layer or the ground layer of first substrate 20, those for power source which are connected to the power-source layer, and those for ground which are connected to the ground layer.

Second IC chip (30B) has through-silicon vias (36B) connecting the upper-surface side and the lower-surface side, solder bumps (38B) on the lower-surface side, and pads (39B) on the upper-surface side. Through-silicon vias (36B), solder bumps (38B) and pads (39B) are the following: those for signal transmission which are not connected to the power-source layer or the ground layer of first substrate 20, those for power source which are connected to the power-source layer, and those for ground which are connected to the ground layer.

Second substrate 50 has solder bumps 58 to be mounted on uppermost second IC chip (30B), power-source layer 54 and ground layer 52. Solder bumps 58 are those for power source which are connected to power-source layer 54 and those for ground which are connected to ground layer 52.

With reference to FIGS. 1B and 1C, reduction of resistance in a power-source supply circuit by using second substrate 50 in the first embodiment is described. Here, FIG. 1B shows a case without second substrate 50, and FIG. 1C shows a case with second substrate 50.

In a case without a second substrate as shown in FIG. 1B, the resistance in a power-source route before reaching point (P) in uppermost second IC chip (30B) is as follows: the resistance in the first substrate ((R1): mainly the resistance in through hole 26 and in power-source layer 24); the resistance in first IC chip (30A) and second IC chip (30B) ((R2): mainly the resistance in through-silicon vias (36A, 36B) and solder bumps (38A, 38B)); the resistance on the surface layer of second IC chip (30B) ((R3): the resistance on the surface-layer route of VDD); and the resistance inside second IC chip (30B) ((R4): the resistance in the interior route of VDD).

Namely, resistance value (R)=(R1)+(R2)+(R3)+(R4)

On the other hand, in a case with the second substrate as shown in FIG. 1C, the power-source route before reaching point (P) in uppermost second IC chip (30B) includes a new route added to the above-described route having resistance (R1) in the first substrate and resistance (R2) in through-silicon vias (36A, 36B) of first IC chip (30A) and second IC chip (30B). The new route is as follows: through-silicon vias (36A, 36B) of adjacent first IC chip (30A) and second IC chip (30B) (resistance (R5): mainly the resistance in through-silicon vias (36A, 36B) and solder bumps (38A, 38B)); and power-source layer 54 in second substrate 50 (resistance (R6): the resistance in solder bump 58 and the resistance in power-source layer 54).

Namely, resistance value (R′)={((R1)+(R2))×((R5)+(R6))}÷{(R1)+(R2)+(R5)+(R6)}+(R3)+(R4)

As for specific values, when R1=958 mΩ, R2=37.1 mΩ, R3=1,796 mΩ, R4=4,926 mΩ, R5=54.6 mΩ and R6=575 mΩ, resistance (R) is 7,717 mΩ in a case without a second substrate shown in FIG. 1B, whereas resistance (R′) is 7,108 mΩ in a case with a second substrate shown in FIG. 1C. When there are two-tiered IC chips, an approximate 8% reduction in resistance may be verified, and a drop in voltage may be lessened before reaching uppermost second IC chip (30B).

In semiconductor device 10 of the first embodiment, in addition to the first route to uppermost second IC chip (30B) (solder bump (38A) of the first IC chip, through-silicon via (36A), solder bump (38B) of the second IC chip and through-silicon via (36B)) which connects power-source layer 24 or ground layer 22 of first substrate 20 and a power-source line or a ground line of the second IC chip, the following routes are formed by mounting second substrate 50 on uppermost second IC chip (30B): the second route (solder bump (38A) of the first IC chip, through-silicon via (36A), solder bump (38B) of the second IC chip and through-silicon via (36B)) which connects power-source layer 24 or ground layer 22 of first substrate 20 and power-source layer 54 or ground layer 52 of second substrate 50; and the third route (solder bump 58) which connects power-source layer 54 or ground layer 52 of second substrate 50 and the power-source line or the ground line of second IC chip (30B). Namely, in a case without a second substrate, a power-source line or a ground line is connected in a series between first substrate 20 and second IC chip (30B) by means of a first route, whereas a power-source supply circuit will make a parallel connection by using second substrate 50, since the second route and the third route are connected parallel to the first route through second substrate 50. Accordingly, resistance in the power-source supply circuit may be reduced.

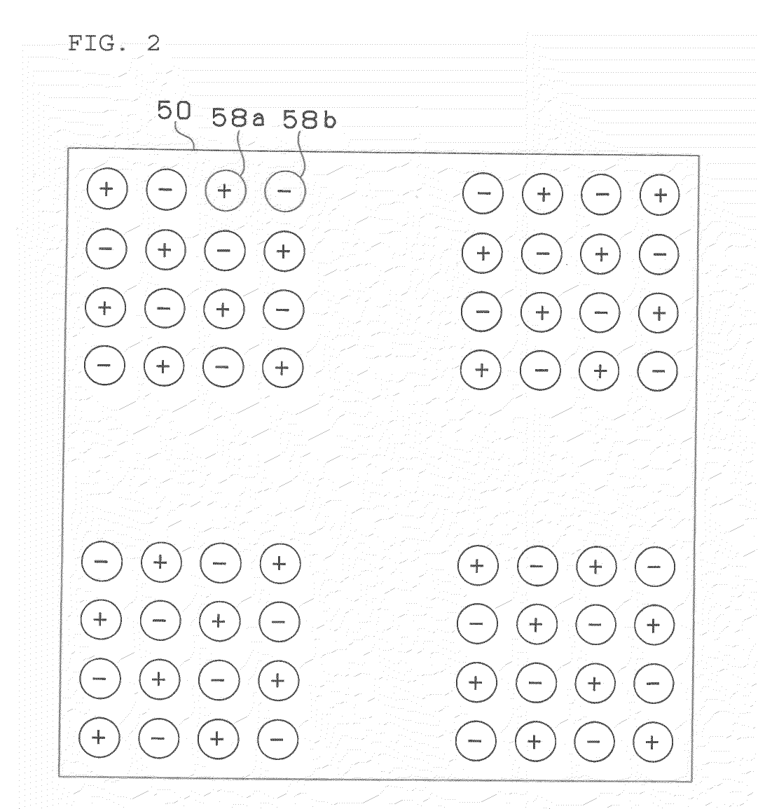

FIG. 2 is a view showing the bottom surface of second substrate 50. Solder bumps are positioned in four corners and there are no solder bumps in the central portion. As for the solder bumps, as described above with reference to FIG. 1, power-source solder bumps (58a) connected to power-source layer 54 and ground solder bumps (58b) connected to ground layer 52 are positioned to make a staggered pattern so that the polarities of adjacent solder bumps will be different. By positioning solder bumps with different polarities to be staggered, magnetic flux to be generated will be offset, and electrical characteristics are improved. However, the positioning of each solder bump is not limited to the above.

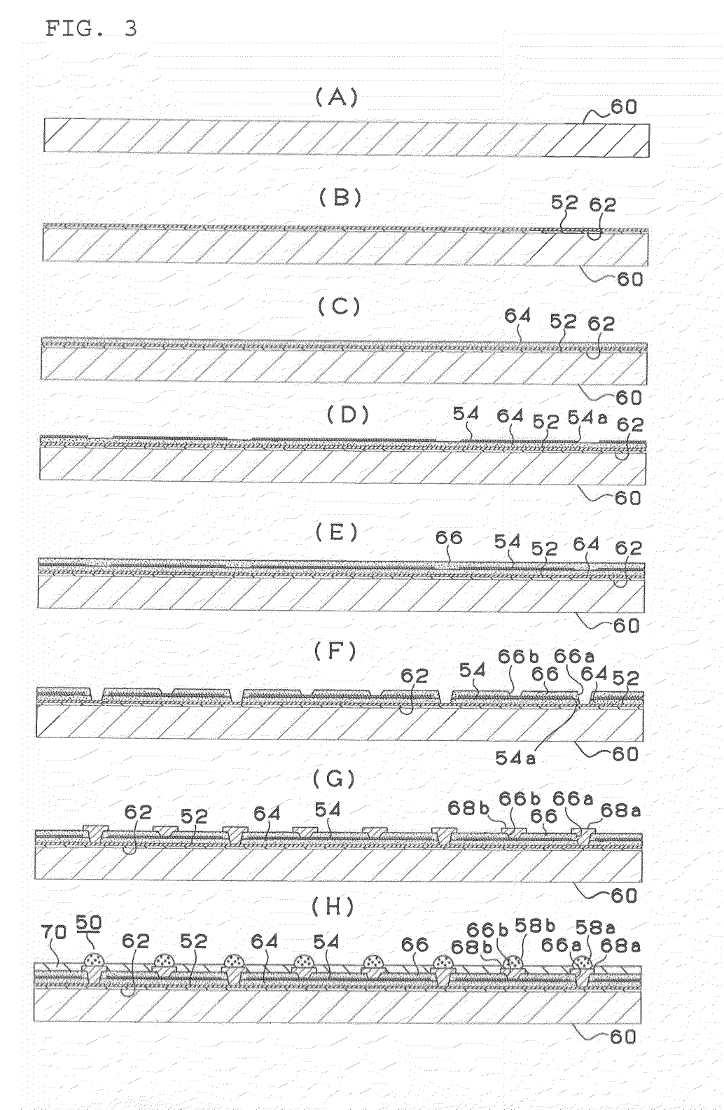

A method for manufacturing second substrate 50 is described with reference to FIG. 3. Substrate 60 shown in FIG. 3A is used. As for the material for forming the substrate, a material with a thermal expansion coefficient of 2-10 ppm is preferred from a viewpoint of making the difference smaller with the thermal expansion coefficient of an IC. For example, silicon, glass, zirconia, aluminum nitride, silicon nitride, silicon carbide, alumina, mullite, cordierite and resin with a low thermal expansion coefficient or the like may be listed. In the present embodiment, a silicon substrate is used.

On silicon substrate 60, insulation layer 62 made of SiO₂ is formed using sputtering, chemical vapor deposition or other technologies, and plain ground layer 52 made of copper plating, for example, is formed on insulation layer 62 (FIG. 3B). Then, first resin insulation layer 64 made of resin, for example, is formed on ground layer 52 (FIG. 3C). Plain power-source layer 54 having opening (54a) and made of copper plating, for example, is formed on first resin insulation layer 64 (FIG. 3D).

Second resin insulation layer 66 made of resin is formed on power-source layer 54 (FIG. 3E). Next, using a laser, opening (66b) is formed to penetrate second resin insulation layer 66 and reach power-source layer 54, and opening (66a) is formed to go through second resin insulation layer 66 and opening (54a), penetrate the first resin insulation layer and reach ground layer 52 (FIG. 3F). Then, after forming electroless plated film, a plating resist layer with a predetermined pattern is formed. After forming an electrolytic plated layer in areas where the plating resist is not formed, power-source via (68a) connected to power-source layer 54, and ground via (68b) connected to ground layer 52 are formed by removing the resist layer and the electroless plated film underneath the resist layer (FIG. 3G). Lastly, solder-resist layer 70 is formed on second resin insulation layer 66, power-source solder bump (58a) is formed on power-source via (68a), and ground solder bump (58b) is formed on ground via (68b). Accordingly, second substrate 50 is completed (FIG. 3H).

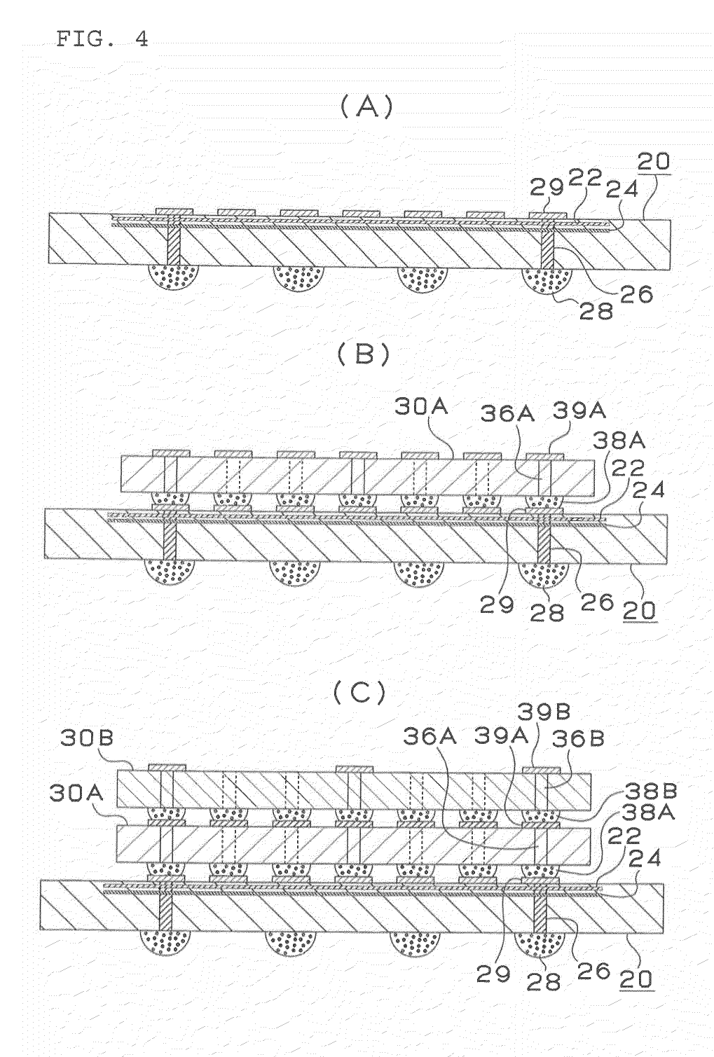

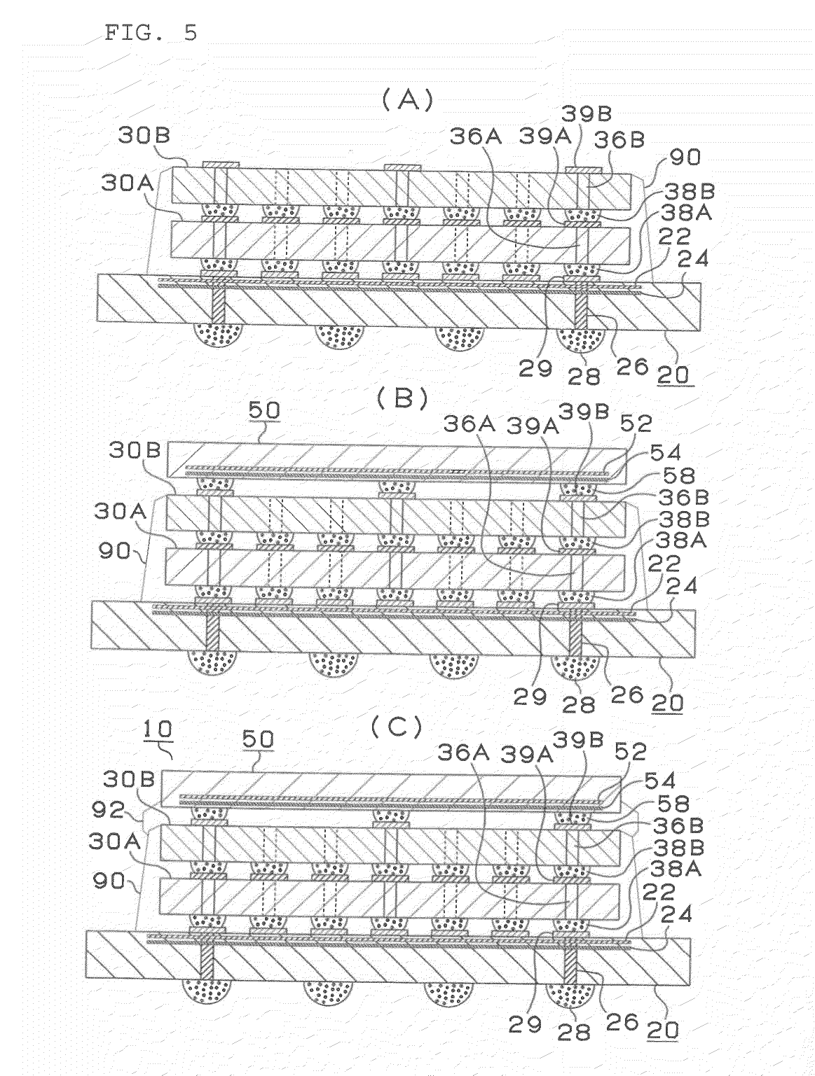

A method for manufacturing semiconductor device 10 is described with reference to FIGS. 4 and 5. First substrate 20 having power-source layer 24 and ground layer 22 as shown in FIG. 4A is used. By reflowing solder bump (38A) on pad 29 of the first substrate, first IC chip (30A) is mounted on first substrate 20 (FIG. 4B). Furthermore, by reflowing solder bump (38B) on pad (39A) of the first IC chip, second IC chip (30B) is mounted on first IC chip (30A) (FIG. 4C).

Then, first substrate 20, first IC chip (30A) and second IC chip (30B) are encapsulated by filling underfill 90 among them (FIG. 5A). Moreover, by reflowing solder bump 58 on pad (39B) of the second IC chip, second substrate 50 is mounted on uppermost second IC chip (30B). Lastly, second IC chip (30B) and second substrate 50 are encapsulated by filling underfill 92 between them. Accordingly, semiconductor device 10 is completed (FIG. 5C).

### First Modified Example of the First Embodiment

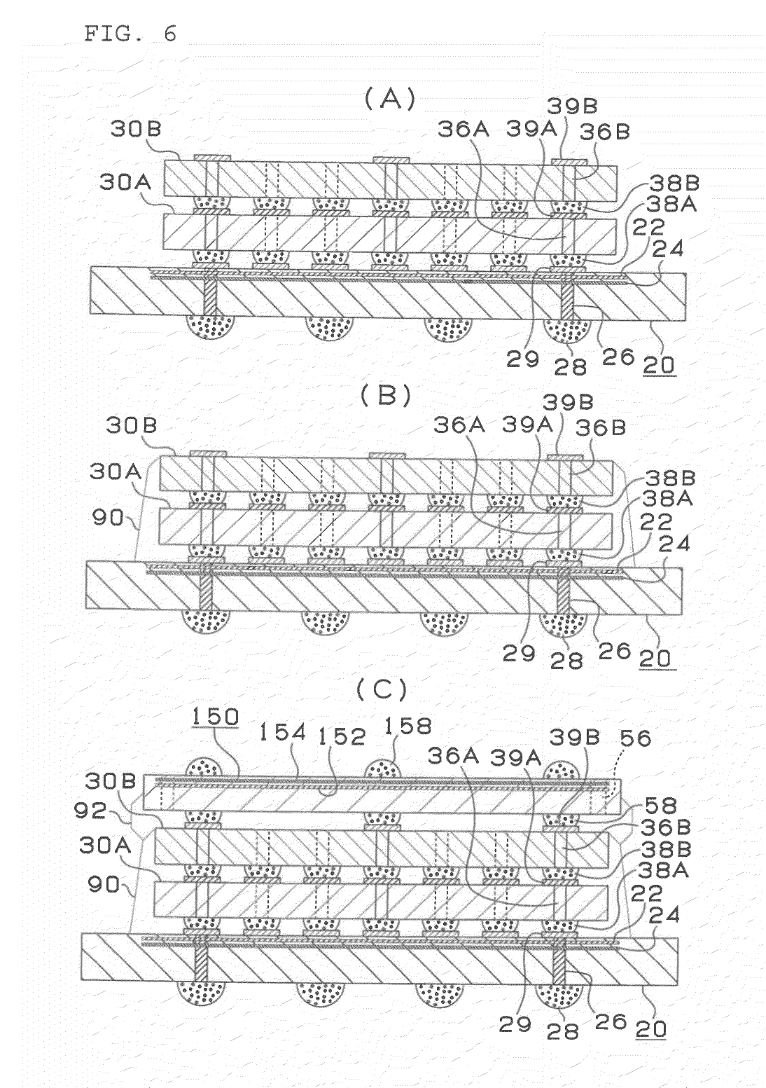

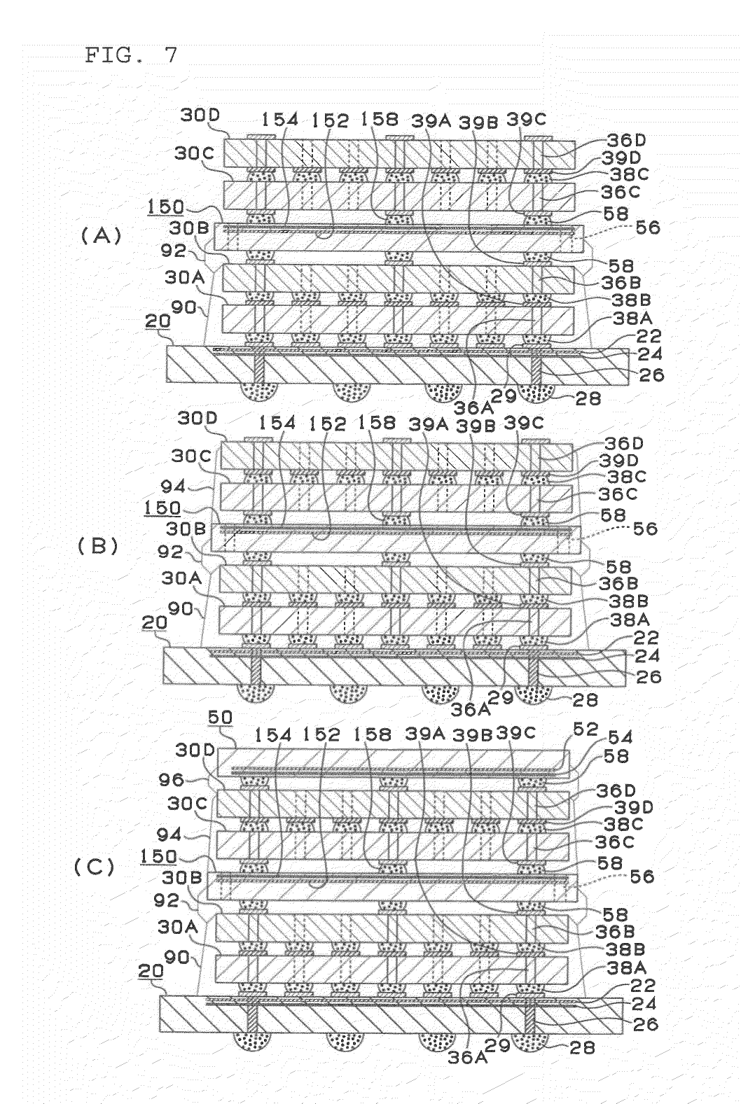

A semiconductor device according to the first modified example of the first embodiment is described with reference to FIGS. 6 and 7.

FIG. 7C shows the structure of a semiconductor device according to the first modified example of the first embodiment. Semiconductor device 10 is formed with first substrate 20 to be mounted on an external substrate, first IC chip (30A) to be mounted on first substrate 20, second IC chip (30B) to be mounted on first IC chip (30A), third substrate 150 to be mounted on second IC chip (30B), third IC chip (30C) to be mounted on third substrate 150, fourth IC chip (30D) to be mounted on third IC chip (30C), and second substrate 50 to be mounted on fourth IC chip (30D). Since the structures of first substrate 20, second substrate 50, first IC chip (30A) and second IC chip (30B) are the same as in the above-mentioned first embodiment, their descriptions are omitted, and only the description of third substrate 150 will be provided.

On the lower-surface side, third substrate 150 has lower-layer side solder bump 58 to be mounted on lower-layer second IC chip (30B), and on the upper-surface side, it has upper-layer side solder bump 158 to be mounted on upper-layer third IC chip (30C), power-source layer 154 and ground layer 152. Through hole 56 to be connected to power-source layer 154 and through hole 56 to be connected to ground layer 152 are formed in third substrate 150.

In a semiconductor device of the first modified example of the first embodiment, resistance of a power-source route to the upper layers may be reduced even if IC chips are stacked three tiers or more.

A method for manufacturing semiconductor device 10 is described with reference to FIGS. 6 and 7. The same as in the first embodiment described above by referring to FIG. 4C, first IC chip (30A) and second IC chip (30B) are mounted on first substrate 20 (FIG. 6A), and first substrate 20, first IC chip (30A) and second IC chip (30B) are encapsulated by filling underfill 90 among them (FIG. 6B). Third substrate 150 is mounted by reflowing solder bump 58 of the third substrate on pad (39B) of second IC chip (30B), and second IC chip (30B) and third substrate 150 are encapsulated by filling underfill 92 between them (FIG. 6C).

Third IC chip (30C) and fourth IC chip (30D) are mounted on third substrate 150 (FIG. 7A), and third substrate 150, third IC chip (30C) and fourth IC chip (30D) are encapsulated by filling underfill 94 among them (FIG. 7B). Second substrate 50 is mounted by reflowing solder bump 58 on pad (39D′) of fourth IC chip (30D), and fourth IC chip (30D) and second substrate 50 are encapsulated by filling underfill 96 between them. Accordingly, the semiconductor device is completed (FIG. 7C).

### Second Modified Example of the First Embodiment

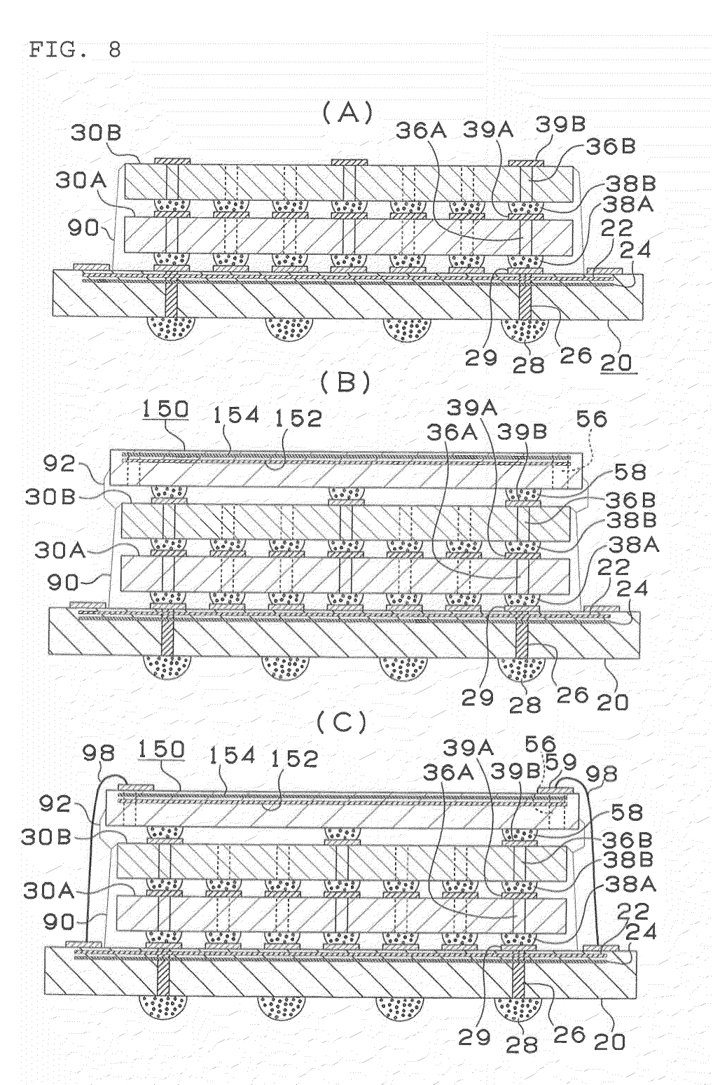

A semiconductor device according to the second modified example of the first embodiment is described with reference to FIG. 8. FIG. 8C shows the structure of a semiconductor device of the second modified example of the first embodiment. Semiconductor device 10 is formed with first substrate 20 to be mounted on an external substrate, first IC chip (30A) to be mounted on first substrate 20, second IC chip (30B) to be mounted on first IC chip (30A), and third substrate 150 to be mounted on second IC chip (30B). In the first embodiment, power source and ground were provided only by through-silicon vias (36A) in the IC chip. By contrast, in the second modified example of the first embodiment, wires 98 for power source and ground are bonded between first substrate 20 and third substrate 150.

A method for manufacturing a semiconductor device according to the second modified example of the first embodiment is described. The same as in the first embodiment described above by referring to FIG. 4C, first IC chip (30A) and second IC chip (30B) are mounted on first substrate 20, and first substrate 20, first IC chip (30A) and second IC chip (30B) are encapsulated by filling underfill 90 among them (FIG. 8A). Third substrate 150 is mounted by reflowing solder bump 58 of the third substrate on pad (39B) of second IC chip (30B), and second IC chip (30B) and third substrate 150 are encapsulated by filling underfill 92 between them. Pad 29 of first substrate 20 and pad 59 of third substrate 150 are bonded with wire 98 (FIG. 6C).

### Second Embodiment

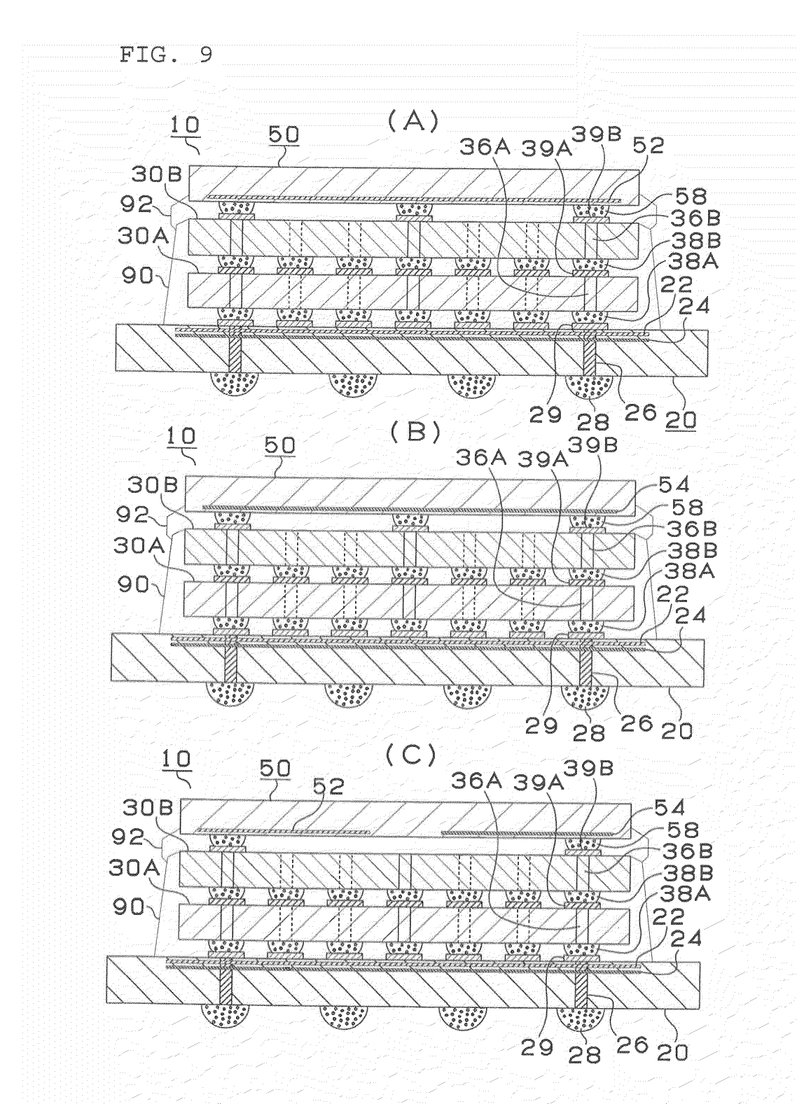

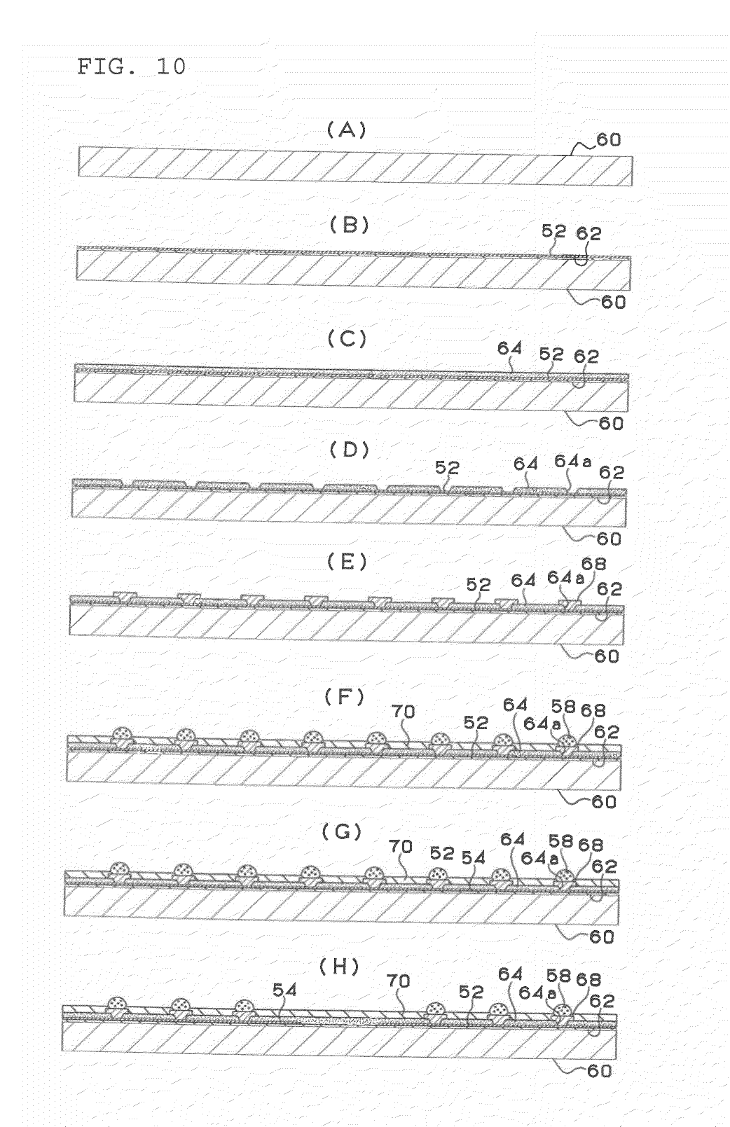

A semiconductor device according to the second embodiment is described with reference to FIGS. 9A and 10. FIG. 9A shows semiconductor device 10 of the second embodiment. Semiconductor device 10 of the second embodiment is formed with first substrate 20 to be mounted on an external substrate, first IC chip (30A) to be mounted on first substrate 20, second IC chip (30B) to be mounted on first IC chip (30A), and second substrate 50 to be mounted on second IC chip (30B). In the first embodiment described above, the second substrate has two layers; a power-source layer and a ground layer. By contrast, the second embodiment has a single-layer structure with only ground layer 52.

A method for manufacturing second substrate 50 according to the second embodiment is described with reference to FIG. 10A-10F. Silicon substrate 60 shown in FIG. 10A is used. On silicon substrate 60, insulation layer 62 made of SiO₂ is formed by using sputtering, chemical vapor deposition or other technologies, and plain ground layer 52 made of copper plating is formed on insulation layer 62 (FIG. 10B). Then, resin insulation layer 64 made of resin, for example, is formed on ground layer 52 (FIG. 10C).

Using a laser, opening (64a) is formed to penetrate resin insulation layer 64 and reach ground layer 52 (FIG. 10D). After forming electroless plated film, a plating resist layer with a predetermined pattern is formed. After forming an electrolytic plated layer in areas where the plating resist is not formed, ground via 68 connected to ground layer 52 is formed by removing the resist layer and the electroless plated film underneath the resist layer (FIG. 10E). Then, solder-resist layer 70 is formed on ground layer 52 and resin insulation layer 64, and ground solder bump 58 is formed on ground via 68. Accordingly, second substrate 50 is completed (FIG. 10F).

In a semiconductor device of the second embodiment, resistance may be reduced in a ground circuit.

### First Modified Example of the Second Embodiment

A semiconductor device according to the first modified example of the second embodiment is described with reference to FIGS. 9B and 10G. In the second embodiment, only a ground layer was formed in second substrate 50. By contrast, in the first modified example of the second embodiment, only power-source layer 54 is formed. In the first modified example of the second embodiment, resistance may be reduced in a power-source circuit.

### Second Modified Example of the Second Embodiment

A semiconductor device according to the second modified example of the second embodiment is described with reference to FIGS. 9C and 10H. In the second embodiment, only a ground layer was formed in second substrate 50. By contrast, in the second modified example of the second embodiment, ground layer 52 and power-source layer 54 are positioned by being shifted from each other in a single-layer structure. In FIG. 9C, ground layer 52 is formed on the left side of second substrate 50, and power-source layer 54 is formed on the right side. In the second modified example of the second embodiment, since power-source and ground supply routes may be increased by a simple structure, resistance may be reduced in a power-source route to upper-layer second IC chip (30B).

In a semiconductor device according to one embodiment of the present invention, a chip-stack structure uses through-silicon vias, and resistance is reduced in a power-source supply circuit. A semiconductor device according to one embodiment of the present invention has a first substrate having a power-source line or a ground line, an IC mounted on the first substrate and having a power-source line or a ground line, and a second substrate mounted on the IC and having a core base material, a power-source layer or a ground layer formed in the core base material, an insulation layer formed on the power-source layer or the ground layer, a pad formed on the insulation layer, and a via conductor connecting the power-source layer or the ground layer and the pad. Such a semiconductor device has the following technological features: a first route connecting the power-source line or the ground line of the first substrate and the power-source line or the ground line of the IC; a second route connecting the power-source line or the ground line of the first substrate and the power-source layer or the ground layer of the second substrate; and a third route connecting the power-source layer or the ground layer of the second substrate and the power-source line or the ground line of the IC.

In a printed wiring board according to one embodiment of the present invention, in addition to a first route to an uppermost IC connecting a power-source line of a first substrate and a power-source line of the IC, by mounting a second substrate on the uppermost IC, the following routes are formed: a second route connecting the power-source line of the first substrate and a power-source layer of the second substrate; and a third route connecting the power-source layer of the second substrate and the power-source line of the IC. Namely, compared with a case without a second substrate, in which a power source is connected in a series between a first substrate and an IC by means of a first route, by using the second substrate, the second route and the third route are connected parallel to the first route through the second substrate. Accordingly, the power-source supply circuit is set to be a parallel circuit and resistance may be reduced in a power-source supply circuit.

Obviously, numerous modifications and variations of the present invention are possible in light of the above teachings. It is therefore to be understood that within the scope of the appended claims, the invention may be practiced otherwise than as specifically described herein.

What is claimed is:

1. A semiconductor device, comprising:
a first substrate having a power-source line;
an IC device mounted on the first substrate and having a power-source line;
a second substrate mounted on the IC device and having a base material, a power-source layer formed inside or on a surface of the base material, an insulation layer formed on the power-source layer, a pad formed on the insulation layer, and a via conductor connecting the power-source layer and the pad;
a first route connecting the power-source line of the first substrate and the power-source line of the IC device;
a second route connecting the power-source line of the first substrate and the power-source layer of the second substrate; and
a third route connecting the power-source layer of the second substrate and the power-source line of the IC device.

2. The semiconductor device according to claim 1, wherein the first route includes a penetrating electrode formed inside the IC device.

3. The semiconductor device according to claim 1, wherein the second route includes a penetrating electrode formed inside the IC device.

4. The semiconductor device according to claim 1, wherein the base material of the second substrate comprises a material having a thermal expansion coefficient set at 2-10 ppm.

5. The semiconductor device according to claim 1, wherein the second substrate has a ground layer and a via conductor which connects the ground layer and the pad.

6. The semiconductor device according to claim 5, wherein the power-source line of the first substrate and the power-source layer of the second substrate are connected by the second route, and the power-source layer of the second substrate and the power-source line of the IC are connected by the third route.

7. The semiconductor device according to claim 5, wherein the power-source layer and the ground layer of the second substrate have a plane form.
